(19) United States
(12) Patent Application Publication
(10) Pub. No.: US 2007/0145592 A1
(43) Pub. Date: Jun. 28, 2007

(54) Semiconductor Device and Method of Manufacturing the Same

(76) Inventor: Young Min Kwon, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/614,106

(22) Filed: Dec. 21, 2006

(30) Foreign Application Priority Data
Dec. 28, 2005 (KR) 10-2005-0131170

(51) Int. Cl. H01L 23/52; H01L 21/4763; H01L 21/473

(52) U.S. Cl. 257/760; 257/774; 438/624; 438/675; 438/787

(57) ABSTRACT

Provided are a semiconductor device and a method for manufacturing the same. The method can include: forming a gate electrode and a source/drain region on a semiconductor substrate; forming a pre metal dielectric insulation layer on the semiconductor substrate, the pre metal dielectric insulation layer including a first insulation layer using a first deposition device and a second insulation layer using a second deposition device, the second deposition device having a relatively higher deposition rate than the first deposition device; and forming a metal pattern on the pre metal dielectric layer, wherein the metal pattern electrically connects to the gate electrode and the source/drain region through the pre metal dielectric insulation layer.

### RELATED APPLICATION(S)

This application claims priority under 35 U.S.C. §119(e) of Korean Patent Application No. 10-2005-0131170 filed Dec. 28, 2005, which is incorporated herein by reference in its entirety.

### FIELD OF THE INVENTION

The present invention relates to a semiconductor device and a method of manufacturing the same.

### BACKGROUND OF THE INVENTION

A semiconductor device can be structurally divided as a bipolar integrated circuit (IC) or a metal-oxide-semiconductor (MOS) IC. A related art semiconductor device manufacturing process will be described as follows.

First, an active region where each semiconductor device will be formed is defined on a silicon wafer, and then each semiconductor device is formed on each active region defined by a fabrication (FAB) process. Finally, a metal layer pattern contacting each electrode region is formed to form an electrode.

At this point, to prevent an electrode region of each device from being electrically shorted by a metal layer pattern, it is required to insulate a silicon wafer having a metal layer and an electrode region.

An insulation layer for insulation of the metal layer and the silicon wafer (an electrode region of each device) may use a phosphor silicate glass (PSG) layer or a boro-phospho silicate glass (BPSG) layer by sub atmosphere chemical vapor deposition (SA CVD) or atmosphere chemical vapor deposition (AP CVD).

FIGS. 1A through 1E are sectional views illustrating a process of manufacturing a related art semiconductor device.

As illustrated in FIG. 1A, a field oxide layer 2 is formed on a device isolation region of a silicon wafer 1 by a trench method or a local oxidation of silicon (LOCOS) method, thereby defining an active region on the silicon wafer 1. A MOS transistor will be formed on the active region. A gate oxide layer and polysilicon are deposited on the defined active region, and then patterned to form a gate electrode.

Next, by using the gate electrode as a mask, impurity is doped in an active region of the silicon wafer 1 to form a source/drain region, and then a spacer is formed on a sidewall of the gate electrode. Accordingly, MOS transistors 3 and 4 are formed on each active region.

Next, since a BPSG layer is deposited as an insulation layer during a subsequent process, and includes a large amount of moisture content, a pre metal dielectric (PMD) liner layer 5 is formed to avoid creating a defect of the silicon wafer 1 and the MOS transistors 3 and 4 and to prevent alkaline ions (Na, K, etc.) from being diffused to the silicon wafer 1.

Next, as illustrated in FIG. 1B, a BPSG layer 6 in a stack structure is formed on the silicon wafer 1 having the PMD liner layer 5 for forming a metal layer thereupon for electrode connection of the MOS transistors 3 and 4 and an insulation layer for insulation of a polysilicon (or a source/drain region). The BPSG layer 6 can be formed by SA CVD or AP CVD.

To improve an insulation property, the BPSG layer 6 is deposited in a stack structure. Moreover, to obtain a certain degree of planarization, the BPSG layer 6 is densely formed through a thermal treatment process.

Next, as illustrated in FIG. 1C, an entire surface of the silicon wafer 1 is planarized by polishing the BPSG layer 6 that is deposited in the stack structure by chemical mechanical polishing (CMP).

As illustrated in FIG. 1D, a contact hole 7 is formed by etching the BPSG layer 6 through a photolithography process to define a portion to which a metal layer and a polysilicon (or a source/drain region) are connected for electrode connection of each of the MOS transistors 3 and 4.

Next, as illustrated in FIG. 1E, a contact barrier metal layer including Ti layer 8 and a TiN layer 9 is formed, and then a contact silicide is formed through a thermal process during a subsequent electrode formation. Next, a metal layer is deposited by sputtering and patterned to form an electrode pattern, thereby forming a final MOS transistor.

The BPSG layer 6 is formed by SA CVD or AP CVD in the related art semiconductor device manufacturing process. However, when SA CVD or AP CVD is performed, deposition rate is very low and it takes more time to form the BPSG layer 6. Accordingly, work productivity decreases, and thus total product yield reduces.

### BRIEF SUMMARY

Accordingly, embodiments of the present invention are directed to a semiconductor device and a method of manufacturing the same that may substantially obviate one or more problems due to limitations and disadvantages of the related art.

An object of an embodiment of the present invention is to provide a semiconductor device capable of reducing a processing time and increasing work productivity to improve product yield and a method of manufacturing the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a semiconductor device, the method including: forming a gate electrode and a source/drain region on a semiconductor substrate; forming a pre metal dielectric insulation layer on the semiconductor substrate, the pre metal dielectric insulation layer comprising a first insulation layer using a first deposition device and a second insulation layer using a second deposition device, the second deposition device having a relatively higher deposition rate than the first deposition device; and forming a metal pattern the pre metal dielectric electrically connected to the gate electrode and the source/drain region through the pre metal dielectric insulation layer.

In another embodiment of the present invention, there is provided a semiconductor device including: a predetermined device formed on a semiconductor substrate; a pre metal dielectric insulation layer comprising first and second insulation layers formed on the device; and a metal pattern electrically connected to the device through the pre metal dielectric insulation layer, the first and second insulation layers formed by using respective first and second deposition devices, the second deposition device having a relatively higher deposition rate than the first deposition device.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIGS. 1A through 1E are sectional views illustrating a process of manufacturing a related art semiconductor device.

FIG. 2 is a sectional view of a semiconductor device according to an embodiment of the present invention.

FIGS. 3A through 3f are sectional views illustrating a process of manufacturing a semiconductor device according to an embodiment of the present invention.

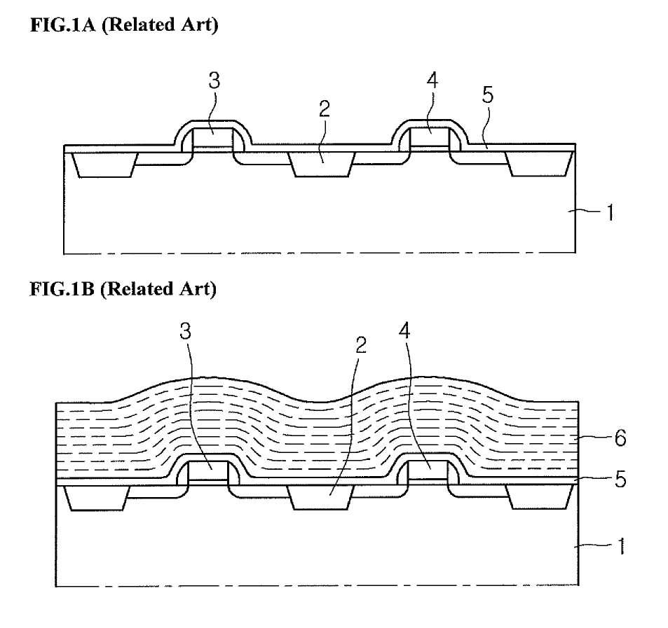

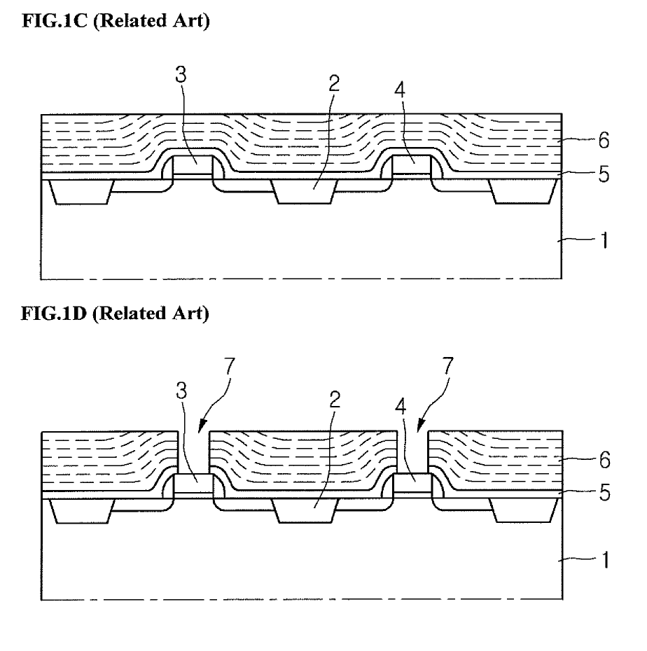

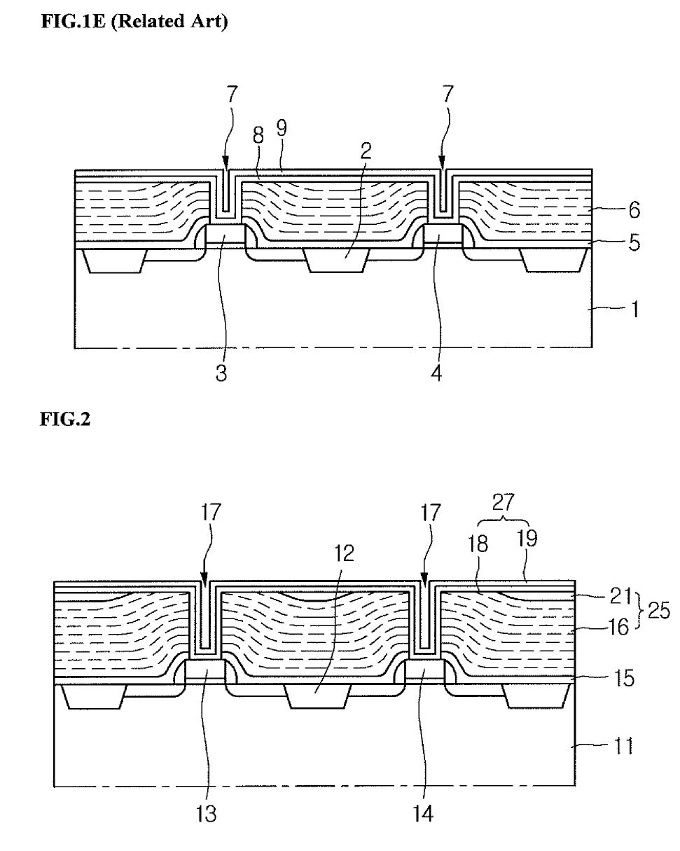

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

In addition, it will also be understood that when a layer is referred to as being ‘between’ two layers, it can be the only layer between the two layers, or one or more intervening layers may also be present.

FIG. 2 is a sectional view of a semiconductor device according to an embodiment of the present invention.

Referring to FIG. 2, a silicon wafer 11 can be divided into an active region where a device such as a MOS transistor is formed and a device isolation region separating each device. In the device isolation region, a field oxide layer 12 can be formed by, for example, a trench method or a local oxidation of silicon (LOCOS) method. Each device is insulated by the field oxidation layer 12 to prevent a short between devices.

A gate electrode that is patterned after depositing a gate oxide layer and a polysilicon layer can be formed on the active region.

A source/drain region doped with impurity can be formed on both sides of the gate electrode. The source/drain region is electrically connected or disconnected by a signal of the gate electrode. In this case, a channel layer, which is electrically connected or disconnected according to a control of the gate electrode, is provided between the source region and the drain region disposed below the gate electrode. The channel layer can be simply a silicon wafer 11, and the channel layer is electrically connected or disconnected by a control of the gate electrode.

A spacer can also be formed on a sidewall of the gate electrode.

Accordingly, MOS transistors 13 and 14 can be formed, incorporating the gate electrode, the spacer, and the source/drain region.

A PMD liner layer 15 can be formed on an entire surface of the silicon wafer 11 to avoid defects of the silicon wafer 11 and the MOS transistors 13 and 14, and to prevent alkaline ions from being diffused into the silicon wafer 11.

A PMD insulation layer 25 including a first insulation layer 16 and a second insulation layer 21 can be formed on the PMD liner layer 15. The first insulation layer 16 can be a PSG layer or a BPSG layer formed by an AP CVD or a SA CVD, and the second insulation layer 21 can be a tetra ethyl ortho silicate (TEOS) layer formed by plasma enhanced chemical vapor deposition (PE CVD). In an embodiment, a thickness ratio between the first insulation layer 16 and the second insulation layer 21 may be 3:1 or 3:2. For example, when the first insulation layer 16 has a thickness of 6000 Å, the second insulation layer 21 may have a thickness of 2000 to 4000 Å. The thickness ratio between the first insulation layer 16 and the second insulation layer 21 can be established after a portion of the second insulation layer 21 is removed by CMP. When considering a thickness before CMP, the thickness ratio between the first insulation layer 16 and the second insulation layer 21 may be 1:1 or 3:4. For example, when the first insulation layer has a thickness of 6000 Å, the second insulation layer 21 may have a thickness of 6000 to 8000 Å. Accordingly, 4000 Å of the second insulation layer 21 may be removed by CMP. At this point, although a portion of the second insulation layer 21 is removed, the first insulation layer 16 is not exposed to the outside. The portion removed by polishing through CMP is limited to a thickness range of the second insulation layer 21. Therefore, the first insulation layer 16, not the second insulation layer 21, may be responsible for a function of the PMD insulation layer 25.

In a related art, because the entire PMD insulation layer is deposited with a low deposition rate by AP CVD or SA CVD, productivity deteriorates. However, according to the present invention, the first insulation layer 16 is formed by AP CVD or SA CVD with a low deposition rate, and the second insulation layer 21 is formed by PE CVD with a high deposition rate. Therefore, the productivity improves. That is, a partial thickness in an entire thickness of the PMD insulation layer 25 is formed of PSG layer or a BPSG layer through AP CVD or SA CVD. The rest of the thickness is formed of a TEOS layer through PE CVD with a high deposition rate. Therefore, the PMD insulation layer 25 can be more rapidly formed to, in some cases, double the work productivity and improve product yield.

A contact hole 17 can be formed in the PMD insulation layer 25 for electrode connection of each of the MOS transistors 13 and 14.

A contact barrier metal layer 27 including a Ti layer 18 and a TiN layer 19 can be formed on the PMD insulation layer 15 having the contact hole 17. A predetermined electrode pattern (not shown) can be formed on the contact barrier metal layer 27.

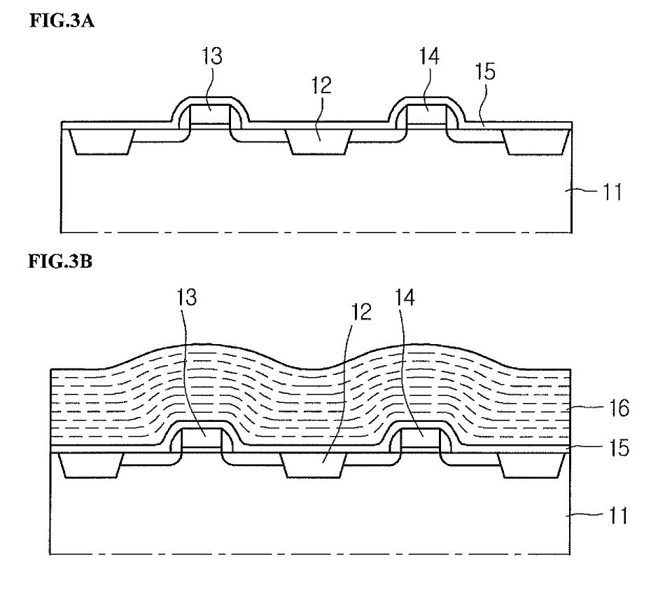

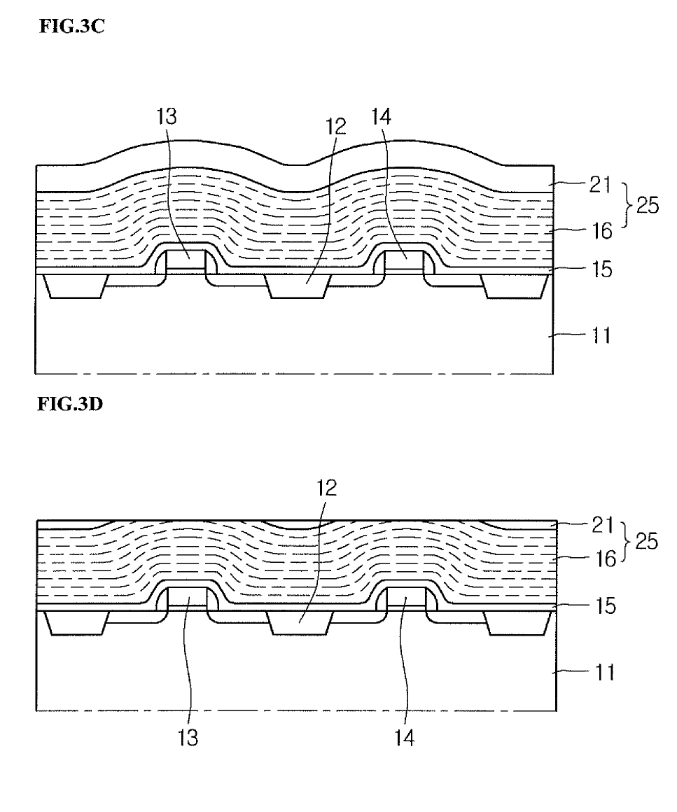

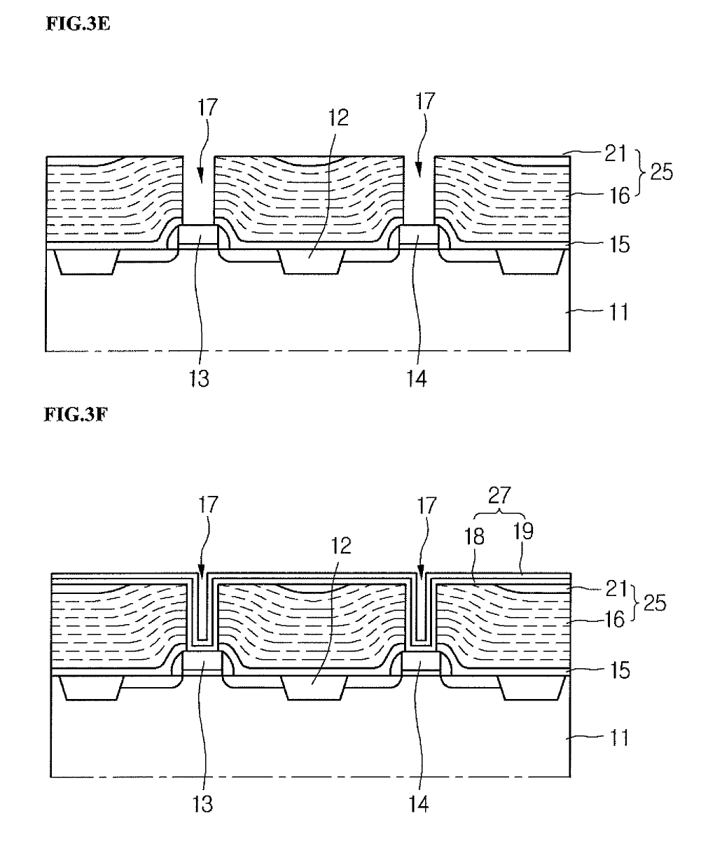

FIGS. 3A through 3f are sectional views illustrating a process of manufacturing a semiconductor device according to an embodiment of the present invention.

Referring to FIGS. 3A, a field oxide layer 12 can be formed on a device isolation region of the silicon wafer 11 by, for example, a trench method or a LOCOS method to define an active region, where MOS transistors 13 and 14 are formed. In an embodiment, an oxide layer and polysilicon can be deposited on the defined active region, and then patterned to form a gate electrode. Next, by using the gate electrode as a mask, impurity can be doped on the active region of the silicon wafer 11 to form MOS transistors 13 and 14 on each active region. Next, since a BPSG layer deposited as an insulation layer includes a large amount of moisture content in a subsequent process, a pre metal dielectric (PMD) liner layer can be formed to avoid a defect of the silicon wafer 11 and the MOS transistor 13 and 14 and to prevent alkaline ions (Na, K, etc.) from being diffused to the silicon wafer 11.

A PMD insulation layer 25 formed of a first insulation layer 16 and a second insulation layer 21 can be formed on the silicon wafer 11 having the PMD liner layer 15. A metal layer for electrode connection of the MOS transistor 13 and 14 can be formed on the PMD insulation layer and the PMD insulation layer can function as an insulation layer for insulation of a polysilicon (or a source/drain region).

Referring to FIG. 3B, in a specific embodiment, the first insulation layer 16, which can be formed of a PSG layer or a BPSG layer, can be formed on the silicon wafer 11 with a thickness of 6000 Å. Next, a thermal process can be performed to obtain a dense and plane first insulation layer 16.

Next, referring to FIG. 3C, after forming the first insulation layer 16, the second insulation layer 21 of a TEOS layer can be deposited with a thickness of 6000 to 8000 Å by using PE CVD with a high deposition rate.

Next, as illustrated in FIG. 3D, an entire surface of the silicon wafer 11 can be planarized by polishing the PMD insulation layer 25 through a CMP process. In a preferred embodiment, a portion removed by polishing (approximately 4000 Å) is the second insulation layer 21, and the first insulation layer 16 is not exposed to the outside. Accordingly, the PMD insulation layer 25 has a thickness of 8000 to 10000 Å after CMP.

Referring to FIG. 3E, the PMD insulation layer 25 can be etched to form a contact hole 17 by a photolithography process to define a portion where a metal layer for electrode connection of the MOS transistor 13 and 14 and a polysilicon (or a source/drain region) of the MOS transistor 13 and 14 are connected.

Next, referring to FIG. 3F, a contact barrier metal layer 27 including a Ti layer 18 and a TiN layer 19 can be formed for reduction of contact resistance and ion diffusion during a subsequent electrode formation. In a further embodiment, a contact silicide can be formed through a thermal process. Next, a metal layer can be deposited through sputtering and patterned to form an electrode pattern (not shown), thereby completing a MOS transistor.

As described above, according to embodiments of the present invention, the PMD insulation layer is formed of a first insulation layer that is a PSG layer or a BPSG layer, and a second insulation layer that is a TEOS layer formed by a PE CVD with a high deposition rate. Then the TEOS layer can be polished by CMP. Therefore, processing time reduces and work productivity increases, thereby improving a product yield.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method of manufacturing a semiconductor device, the method comprising:
forming a gate electrode and a source/drain region on a semiconductor substrate;
forming a pre metal dielectric insulation layer on the semiconductor substrate by forming a first insulation layer using a first deposition device and forming a second insulation layer on the first insulation layer using a second deposition device, wherein the second deposition device has a relatively higher deposition rate than the first deposition device; and
forming a metal pattern on the pre metal dielectric insulation layer, wherein the metal pattern electrically connects with the gate electrode and the source/drain region through the pre metal dielectric insulation layer.

2. The method according to claim 1, wherein the first deposition device is an atmosphere chemical vapor deposition device or a sub atmosphere chemical vapor deposition device, and the second deposition device is a plasma enhanced chemical vapor deposition device.

3. The method according to claim 1, wherein the first insulation layer is formed of phosphor silicate glass or boro-phospho silicate glass, and the second insulation layer is formed of tetra ethyl ortho silicate.

4. The method according to claim 1, wherein a thickness ratio between the first and second insulation layers is 1:1 or 3:4.

5. The method according to claim 1, further comprising polishing the pre metal dielectric insulation layer by chemical mechanical polishing.

6. The method according to claim 5, wherein only the second insulation layer is polished by the chemical mechanical polishing.

7. The method according to claim 5, wherein a thickness ratio of the first and second insulation layers is 3:1 after the chemical mechanical polishing.

8. The method according to claim 1, wherein the forming of the pre metal dielectric insulation layer comprises:
depositing the first insulation layer by using the first deposition device;
performing a thermal treatment on the first insulation layer; and
depositing the second insulation layer on the thermally treated first insulation layer by using the second deposition device.

9. A semiconductor device, comprising:
a predetermined device on a semiconductor substrate;
a pre metal dielectric insulation layer comprising first and second insulation layers formed on the device; and
a metal pattern on the pre metal dielectric insulation layer, wherein the metal pattern electrically connects to the device through the pre metal dielectric insulation layer, wherein the first and second insulation layers are formed by using respective first and second deposition devices, the second deposition device having a relatively higher deposition rate than the first deposition device.

10. The semiconductor device according to claim 9, wherein the first insulation layer is formed of phosphor silicate glass or boro-phospho silicate glass, and the second insulation layer is formed of a tetra ethyl ortho silicate.

11. The semiconductor device according to claim 9, wherein a thickness ratio between the first and second insulation layers is 3:1.

12. The semiconductor device according to claim 9, wherein the pre metal dielectric insulation layer is polished by using chemical mechanical polishing.
